(19) United States
(12) Patent Application Publication
(10) Pub. No.: US 2017/0084628 A1
(43) Pub. Date: Mar. 23, 2017

(54) SUBSTRATE-TRANSFERRED, DEEP TRENCH ISOLATION SILICON-ON-INSULATOR (SOI) SEMICONDUCTOR DEVICES FORMED FROM BULK SEMICONDUCTOR WAFERS

(71) Applicant: QUALCOMM Incorporated, San Diego, CA (US)

(72) Inventors: Daeik Daniel Kim, Del Mar, CA (US); Changhan Hobie Yun, San Diego, CA (US); Je-Hsiung Jeffrey Lan, San Diego, CA (US); Jonghae Kim, San Diego, CA (US); Matthew Michael Nowak, San Diego, CA (US)

(21) Appl. No.: 14/858,203

(22) Filed: Sep. 18, 2015

(51) Int. Cl. H01L 27/12; H01L 21/762

(52) U.S. Cl. CPC H01L 27/1203; H01L 21/76264

(57) ABSTRACT

Substrate-transferred, deep trench isolation silicon-on-insulator (SOI) semiconductor devices formed from bulk semiconductor wafers are disclosed. In this regard, a bulk semiconductor wafer is provided that includes a bulk body, one or more transistors formed in the bulk body, and deep trenches formed between the transistors formed in the bulk body to provide isolation between the transistors. To prevent the bulk body from electrically interconnecting the transistors, the bulk body is thinned near, at, or beyond a back side of the deep trenches formed in the bulk body to form separate bulk bodies for each transistor isolated by the deep trenches. An insulation substrate is bonded to the bulk semiconductor device to form an SOI wafer. In this manner, residual bulk bodies of the transistors in the SOI wafer are isolated between the deep trenches and the insulation substrate to reduce or avoid leakage current between transistors.

### BACKGROUND

I. Field of the Disclosure

The technology of the disclosure relates generally to bulk and silicon-on-insulator (SOI) complementary metal oxide semiconductor (CMOS) devices, and particularly to isolation of transistors formed in such devices.

II. Background

Silicon wafers are commonly used for providing semiconductor devices. For example, in a bulk complementary metal oxide semiconductor (CMOS) device, transistors are formed in a bulk silicon body layer. Shallow trench isolation (STI) is employed to provide some isolation between adjacent transistors in the CMOS device. However, the bulk silicon body layer of the transistors in the CMOS device is connected. As a result, the transistors in the CMOS device are not completely isolated. Also, bulk CMOS devices are not particularly suited for radio frequency (RF) applications in which higher voltages are coupled (e.g., 25V), as bulk CMOS devices encounter device breakdown at higher voltage levels.

To provide isolation between adjacent transistors in a semiconductor device, silicon-on-insulator (SOI) wafers have been introduced. In SOI wafers, transistors are formed in thin layers of silicon that are isolated from a main body of an SOI wafer handle substrate by a layer of an electrical insulator, usually silicon dioxide. The silicon layer thickness ranges from several microns for electrical power switching devices to less than 500 Angstroms for high-performance microprocessors. Isolating an active transistor from the rest of a silicon substrate reduces electrical current leakage that would otherwise degrade the performance of the transistor. Since the area of electrically active silicon is limited to the immediate region around the transistor, switching speeds are increased and sensitivity to “soft errors” is greatly reduced.

In this regard, FIG. 1 is an exemplary SOI wafer 100. Instead of forming transistors in a bulk silicon layer, a transistor 102 is formed in a top, thin surface silicon layer 104 (“silicon layer 104”) above an underlying insulating layer 106 that is usually a few thousand Angstroms thick. The insulating layer 106 is formed on a handle substrate layer 108, which may be a silicon (Si) wafer and that provides a main body of the SOI wafer 100. The insulating layer 106 may be made out of silicon dioxide and referred to as a “buried oxide” or “BOX” layer to electrically isolate the silicon layer 104 from the handle substrate layer 108. The transistor 102 being formed within the silicon layer 104 allows for faster switching speeds, operation at lower voltages, and provides for the transistor 102 to be much less vulnerable to noise from background cosmic ray particles. Also, by the transistor 102 being isolated from its neighbor transistors (not shown) in the SOI wafer 100, the transistor 102 can be more closely located to other transistors in the SOI wafer 100 to yield more chips per SOI wafer 100.

During the bonding process of the SOI wafer 100 in FIG. 1, a semiconductor layer 110 may be formed between the insulating layer 106 and the handle substrate layer 108 due to the high temperature, voltage, and pressure used to form the transistor 102. This causes carriers of a depletion layer to move toward the insulating layer 106, and causes the semiconductor layer 110 to be formed between the insulating layer 106 and the handle substrate layer 108. The semiconductor layer 110 forms a varactor 112 that has a capacitance based on voltage applied to the transistor 102. This reduces the insulation between the transistor 102 and the handle substrate layer 108, thereby increasing current leakage between the transistor 102 and adjacent transistors through the handle substrate layer 108. Not only does the semiconductor layer 110 formed between the insulating layer 106 and the handle substrate layer 108 increase RF leakage current between the transistor 102 and adjacent transistors, but it also induces non-linearity and power loss in the transistor 102. Depending on the application of the SOI wafer 100, this non-linearity and RF power loss in the transistor 102 may significantly impact performance of the circuits employing the transistor 102 in the SOI wafer 100.

### SUMMARY OF THE DISCLOSURE

Aspects disclosed in the detailed description include substrate-transferred, deep trench isolation silicon-on-insulator (SOI) semiconductor devices formed from bulk semiconductor wafers. Related methods and circuits are also disclosed. In this regard, in one aspect, a bulk semiconductor wafer is provided. The bulk semiconductor wafer may be a complementary metal oxide semiconductor (CMOS) device. The bulk semiconductor wafer includes a bulk body layer, also known as a “bulk body.” The bulk body may be a silicon bulk body. One or more transistors are formed in the bulk body of the bulk semiconductor wafer. Deep trenches are formed between the transistors formed in the bulk body (e.g., in a front end-of-line (FEOL) process) to provide current leakage isolation between the transistors. However, to prevent the bulk body in the bulk semiconductor wafer from electrically interconnecting the transistors, and defeating the isolation of the deep trenches, aspects disclosed herein involve the bulk body being thinned near, at, or beyond the back side of the deep trenches formed in the bulk body. As a result, the bulk body of the transistors is separated into separate bulk bodies for each transistor isolated by the deep trenches. An insulation substrate, such as glass for example, is then bonded to the bulk semiconductor wafer (e.g., in a back end-of-line (BEOL) process) to form an SOI wafer. In this manner, the residual bulk bodies of the transistors are isolated between the deep trenches and the insulation substrate to reduce or avoid leakage current between transistors. However, by the SOI wafer being formed from a bulk semiconductor wafer, the formation of a semiconductor layer between the insulation substrate and the transistors during fabrication is reduced or avoided, thereby reducing non-linearity and power loss of the transistors. This may allow the SOI wafer to be particularly suited for semiconductor devices for radio-frequency (RF) applications, as a non-limiting example.

In this regard, in one exemplary aspect, an SOI wafer is provided. The SOI wafer comprises an insulation substrate comprising a top side and a back side. The SOI wafer also comprises an active semiconductor layer disposed above the insulation substrate, the active semiconductor layer comprising a bulk body and a plurality of transistors formed in the bulk body. The SOI wafer also comprises one or more deep trenches disposed in the bulk body to the top side of the insulation substrate and between adjacent transistors among the plurality of transistors.

In another exemplary aspect, an SOI wafer is provided. The SOI wafer comprises a means for insulating comprising a top side and a back side. The SOI wafer also comprises a means for providing an active semiconductor layer disposed above the means for insulating, the means for providing the active semiconductor layer comprising a bulk body and a plurality of transistors formed in the bulk body. The SOI wafer also comprises a means disposed in the bulk body to the top side of the means for insulating, for providing isolation between adjacent transistors among the plurality of transistors.

In another exemplary aspect, a method of fabricating an SOI wafer is provided. The method comprises providing a bulk body layer comprising a top side and a back side. The method also comprises forming an active semiconductor layer comprising one or more transistors in the top side of the bulk body layer. The method also comprises forming one or more deep trenches in the top side of the bulk body layer between adjacent transistors among the one or more transistors. The one or more deep trenches each comprises a top side disposed toward the top side of the bulk body layer and a back side disposed toward the back side of the bulk body layer. The method also comprises removing a portion of the bulk body layer from the back side of the bulk body layer towards the back side of the one or more deep trenches to form a residual bulk body. The method also comprises disposing an insulation substrate on a back side of the residual bulk body.

### BRIEF DESCRIPTION OF THE FIGURES

FIG. 1 is a block diagram of an exemplary silicon-on-insulator (SOI) wafer employing a silicon layer substrate;

FIG. 2 a block diagram of an exemplary substrate-transferred, deep trench isolation SOI wafer formed from a bulk semiconductor device, to provide current leakage isolation between transistors formed in the SOI wafer;

FIGS. 3A-3E are block diagrams illustrating exemplary fabrication stages of forming the substrate-transferred, deep trench isolation SOI wafer in FIG. 2 from a bulk semiconductor wafer;

FIGS. 4A-4C are flowcharts illustrating an exemplary process of fabricating the substrate-transferred, deep trench isolation SOI wafer from a bulk semiconductor wafer; and

FIG. 5 is a block diagram of an exemplary processor-based system that can include circuits that include semiconductor devices comprising substrate-transferred, deep trench isolation SOI wafers formed from bulk semiconductor wafers to improve isolation and reduce current leakage between transistors formed in the SOI wafer, and according to any of the aspects disclosed herein.

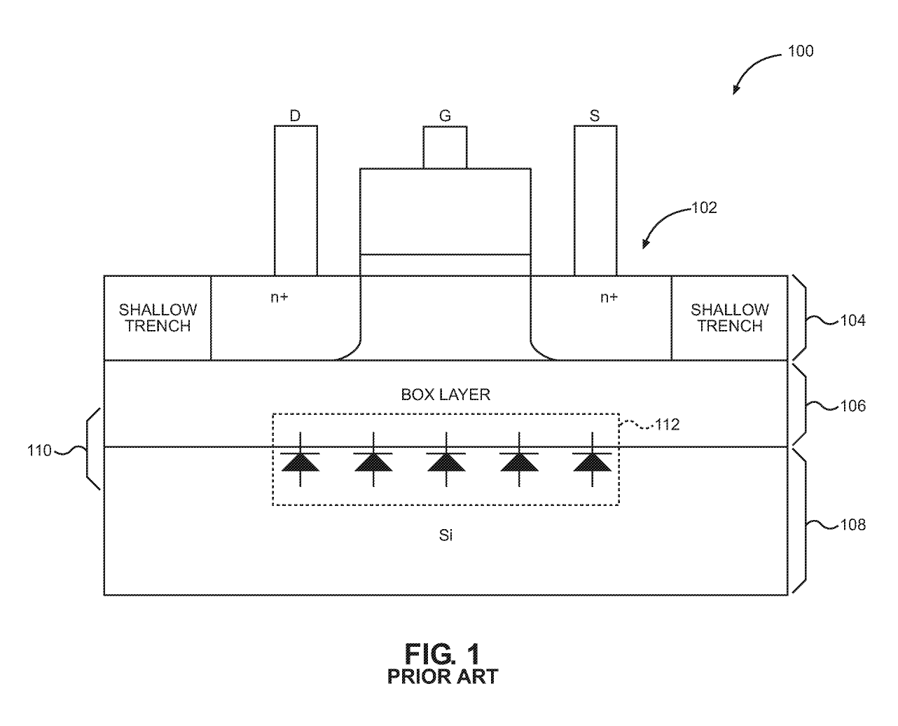

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include substrate-transferred, deep trench isolation silicon-on-insulator (SOI) semiconductor devices formed from bulk semiconductor wafers. Related methods and circuits are also disclosed. In this regard, in one aspect, a bulk semiconductor wafer is provided. The bulk semiconductor wafer may be a complementary metal oxide semiconductor (CMOS) device. The bulk semiconductor wafer includes a bulk body layer, also known as a “bulk body.” The bulk body may be a silicon bulk body. One or more transistors are formed in the bulk body of the bulk semiconductor wafer. Deep trenches are formed between the transistors formed in the bulk body (e.g., in a front end-of-line (FEOL) process) to provide current leakage isolation between the transistors. However, to prevent the bulk body in the bulk semiconductor wafer from electrically interconnecting the transistors, and defeating the isolation of the deep trenches, aspects disclosed herein involve the bulk body being thinned near, at, or beyond the back side of the deep trenches formed in the bulk body. As a result, the bulk body of the transistors is separated into separate bulk bodies for each transistor isolated by the deep trenches. An insulation substrate, such as glass for example, is then bonded to the bulk semiconductor wafer (e.g., in a back end-of-line (BEOL) process) to form an SOI wafer. In this manner, the residual bulk bodies of the transistors are isolated between the deep trenches and the insulation substrate to reduce or avoid leakage current between transistors. However, by the SOI wafer being formed from a bulk semiconductor wafer, the formation of a semiconductor layer between the insulation substrate and the transistors during fabrication is reduced or avoided, thereby reducing non-linearity and radio-frequency (RF) power loss of the transistors. This may allow the SOI wafer to be particularly suited for semiconductor devices for radio-frequency (RF) applications, as a non-limiting example.

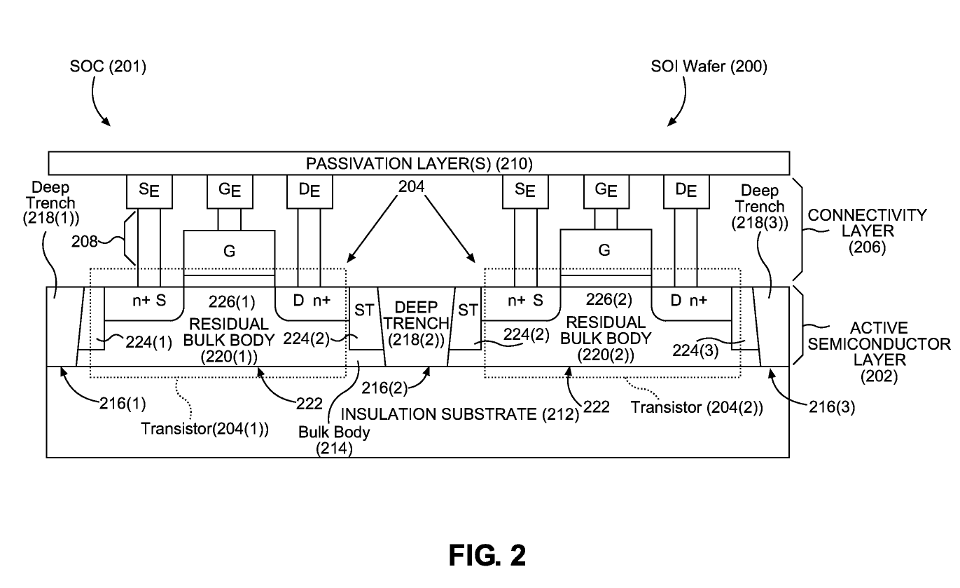

In this regard, FIG. 2 is a block diagram of one exemplary finalized SOI wafer 200 formed from a bulk semiconductor wafer. The finalized SOI wafer 200 may be included in a system-on-a-chip (SoC) 201 as a non-limiting example. The finalized SOI wafer 200 includes an active semiconductor layer 202 with transistors 204 formed therein. In the example shown in FIG. 2, only two transistors 204(1), 204(2) are shown formed in the active semiconductor layer 202. However, more transistors 204 can be formed in the active semiconductor layer 202. A connectivity layer 206 provides connectivity between drain (D), source (S), and gate (G) nodes of the transistors 204(1), 204(2) to drain electrodes (DE), source electrodes (SE), and gate electrodes (GE) for the transistors 204(1), 204(2) to support connectivity to other circuits. For example, the connectivity layer 206 may include one or more vias 208 to provide connectivity between the drain (D), source (S), and gate (G) nodes of the transistors 204(1), 204(2) to the drain electrodes (DE), source electrodes (SE), and gate electrodes (GE). One or more passivation layers 210 is disposed above the drain electrodes (DE), source electrodes (SE), and gate electrodes (GE) to isolate the drain electrodes (DE), source electrodes (SE), and gate electrodes (GE) from other circuits or components.

As discussed in more detail below, the finalized SOI wafer 200 in FIG. 2 also has an insulation substrate 212 that was transferred onto a back side of a bulk body 214 of a bulk semiconductor wafer to form the finalized SOI wafer 200. The insulation substrate 212 was transferred after a portion of a back side (not shown in FIG. 2) of the bulk body 214 of the transistors 204(1), 204(2) was removed to respective back sides 216(1)-216(3) of deep trenches 218(1)-218(3). In this manner, isolated residual bulk bodies 220(1), 220(2) of the transistors 204(1), 204(2) are formed as a result of removing a portion of the back side of the bulk body 214 and the insulation substrate 212 being transferred to a back side of the residual bulk bodies 220(1), 220(2) and the back sides 216(1)-216(3) of the deep trenches 218(1)-218(3). The residual bulk bodies 220(1), 220(2) serve a similar purpose to a buried oxide (BOX) layer in a traditional SOI wafer. The residual bulk bodies 220(1), 220(2) are electrically isolated from each other to reduce or avoid leakage current flowing from one transistor 204(1) to the other transistor 204(2), because the deep trenches 218(1)-218(3) extend to a top side 222 of the insulation substrate 212 in this example. The deep trenches 218(1)-218(3) may be formed over shallow trenches (ST) 224(1)-224(3) that were formed in the bulk body 214 of the finalized SOI wafer 200 to provide shallow trench isolation for the residual bulk bodies 220(1), 220(2), as shown in FIG. 2.

Also, by the finalized SOI wafer 200 in FIG. 2 being formed from a bulk semiconductor wafer, the formation of a varactor layer between the insulation substrate 212 and the transistors 204(1), 204(2) that may otherwise form during fabrication of a traditional SOI wafer be may be reduced or avoided, thereby reducing non-linearity and power loss issues with the formed transistors 204(1), 204(2). In a traditional SOI wafer fabrication process, the application of higher temperature, voltage, and pressure used to form transistors therein can cause non-linearity and power loss of the transistors 204(1), 204(2). Thus, the finalized SOI wafer 200 in FIG. 2 being formed from a bulk semiconductor wafer allows for improved electrical isolation between channel regions 226(1), 226(2) of the transistors 204(1), 204(2), and also allows the finalized SOI wafer 200 to be particularly suited for semiconductor devices for RF applications that are susceptible to non-linearity and power loss issues, as a non-limiting example.

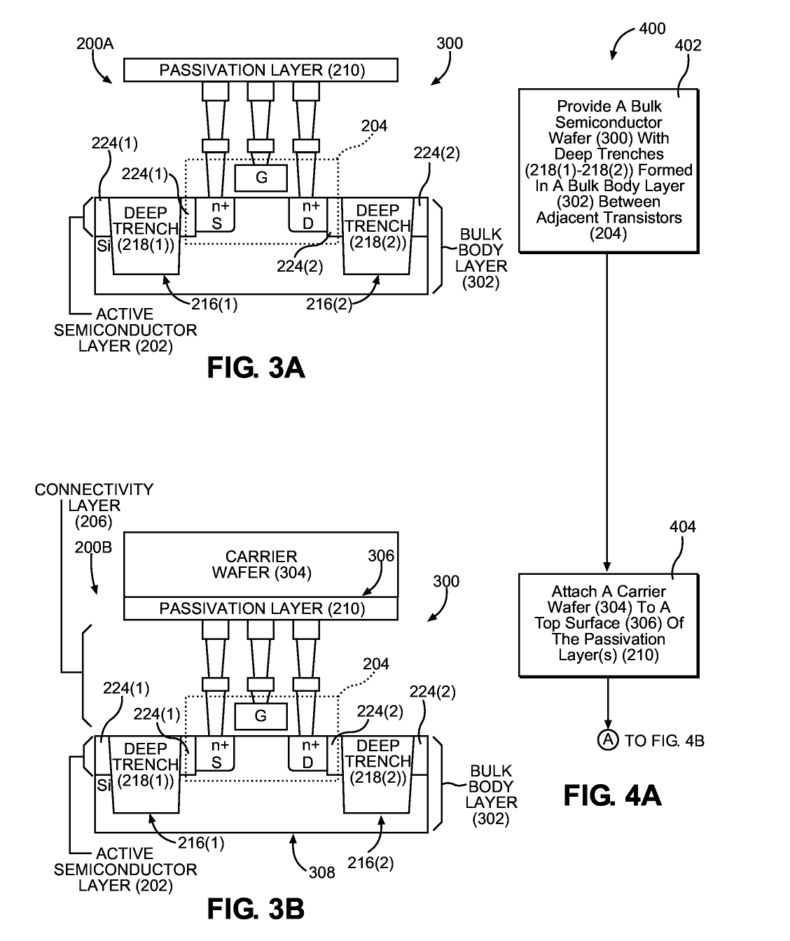

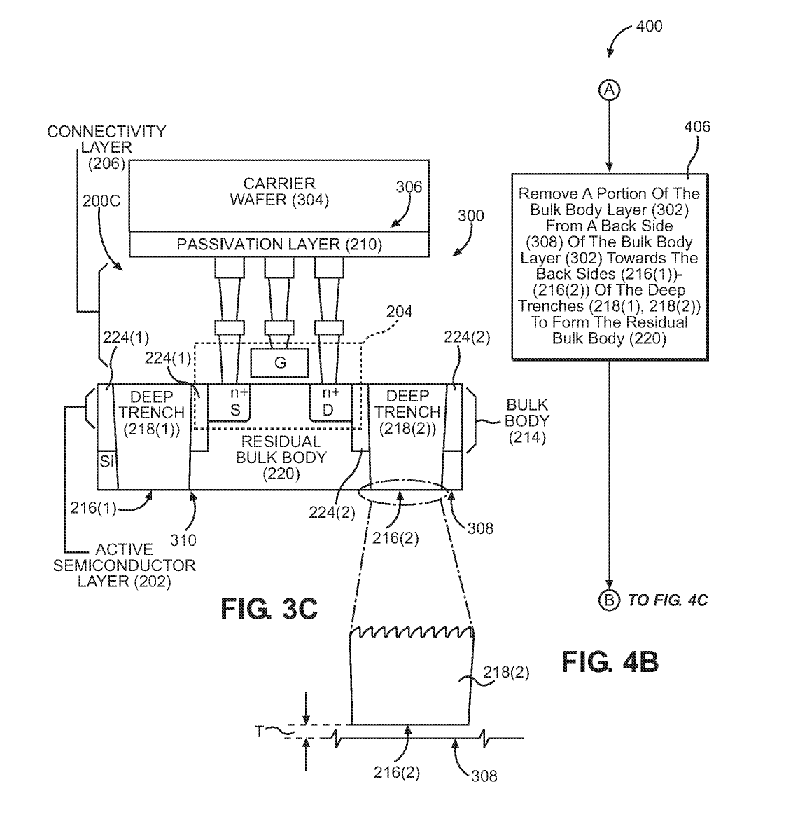

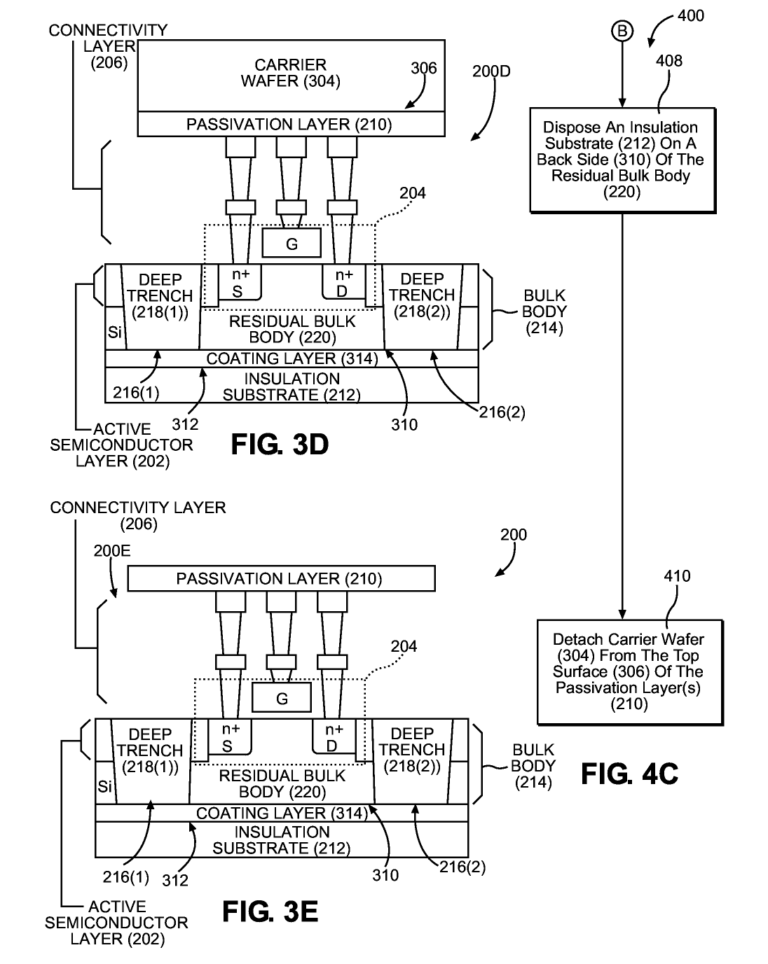

FIGS. 3A-3E are block diagrams illustrating stages of the finalized SOI wafer 200 in FIG. 2 during exemplary fabrication stages to provide a transferred insulation substrate to a bulk semiconductor wafer 300 to form the finalized SOI wafer 200. In this regard, FIGS. 3A-3E illustrate semiconductor wafers 200A-200E illustrating a single transistor 204 during exemplary fabrication stages. Common components between the semiconductor wafers 200A-200E in FIGS. 3A-3E and the finalized SOI wafer 200 in FIG. 2 are shown with common element numbers between FIG. 2 and FIGS. 3A-3E. FIGS. 4A-4C are flowcharts illustrating an exemplary process 400 of forming the finalized SOI wafer 200 in FIG. 2.

In this regard, with reference to FIG. 3A, a semiconductor wafer 200A is provided in the form of the bulk semiconductor wafer 300 that is first fabricated and provided to form the finalized SOI wafer 200 (block 402 in FIG. 4A). A transistor 204 is shown formed in the active semiconductor layer 202. The transistor 204 is shown as an N-type MOS (NMOS) transistor for its enhanced carrier mobility, but the transistor 204 could also be a P-type MOS (PMOS) transistor. As previously discussed, the connectivity layer 206 provides connectivity between drain (D), source (S), and gate (G) nodes of the transistors 204(1), 204(2) to drain electrodes (DE), source electrodes (SE), and gate electrodes (GE) for the transistors 204(1), 204(2) to support connectivity to other circuits. For example, the connectivity layer 206 may include the one or more vias 208 in FIG. 2 to provide connectivity between the drain (D), source (S), and gate (G) nodes of the transistors 204(1), 204(2) to the respective drain electrodes (DE), source electrodes (SE), and gate electrodes (GE). One or more passivation layers 210 are provided to isolate the connectivity layer 206 from other circuits or components. The bulk semiconductor wafer 300 has the deep trenches 218(1), 218(2) formed in a bulk body layer 302 in a FEOL process so that electrical isolation can be provided between the transistor 204 and adjacent transistors (not shown) formed in the bulk semiconductor wafer 300. The deep trenches 218(1), 218(2) may be formed in the respective shallow trenches 224(1), 224(2). Non-limiting examples of materials that may be formed in the bulk semiconductor wafer 300 to form the deep trenches 218(1), 218(2) include silicon nitride or silicon oxide. The bulk body layer 302 may be a silicon (Si) layer or a silicon-based layer as examples. Because the bulk semiconductor wafer 300 does not include a BOX layer formed between the transistor 204 and another substrate, a varactor is not formed that contributes to current leakage due to the high temperature, voltage, and pressure used to form the transistor 204.

Next, as shown in FIG. 3B, a carrier wafer 304 is attached to a top surface 306 of the passivation layer 210 to form the SOI wafer 200B so that the bulk semiconductor wafer 300 can be handled during further fabrication steps (block 404 in FIG. 4A). Next, to prepare for the insulation substrate 212 (see FIG. 2) to be provided as a substrate for the bulk semiconductor wafer 300 to form the finalized SOI wafer 200, a portion of the bulk body layer 302 is removed from a back side 308 of the bulk body layer 302 to form the SOI wafer 200C in FIG. 3C (block 406 in FIG. 4B). The portion of the removed bulk body layer 302 is removed towards the back sides 216(1), 216(2) of the deep trenches 218(1), 218(2) to provide the bulk body 214 for the finalized SOI wafer 200 to be formed. In this manner, the residual bulk body 220 is formed that is electrically isolated from adjacent transistors (not shown) formed in the bulk semiconductor wafer 300. This is because the bulk body layer 302 is removed down to the back sides 216(1), 216(2) of the deep trenches 218(1), 218(2) such that the deep trenches 218(1), 218(2) provide electrical isolation in this example. There is no bulk body layer 302 disposed beneath the back sides 216(1), 216(2) of the deep trenches 218(1), 218(2) that is also connected to an adjacent transistor to allow for current leakage. As a non-limiting example, a portion of the bulk body layer 302 may be removed through a back side grinding process. Alternatively, the portion of the bulk body layer 302 may be removed through an etching and/or chemical removal process.

As non-limiting examples, a portion of the bulk body layer 302 could be removed so that a back side 310 of the bulk body 214 is near the back sides 216(1), 216(2) of the deep trenches 218(1), 218(2). For example, the back side 310 of the bulk body 214 may be processed to be within one (1) to ten (10) micrometers (μm), such as from three (3) to five (5) μm for example, from the back sides 216(1), 216(2) of the deep trenches 218(1), 218(2). In this case, the back sides 216(1), 216(2) of the deep trenches 218(1), 218(2) are not fully exposed. For example, the deep trenches 218(1), 218(2) can be formed in the bulk semiconductor wafer 300 to be ten (10) to fifteen (15) μm deep.

Also, the removal process used to remove a portion of the bulk body layer 302 may not be able to fully sense the exact location of the back sides 216(1), 216(2) of the deep trenches 218(1), 218(2). Thus, the amount of the bulk body layer 302 removed could be distance based.

Alternatively, enough of a portion of the bulk body layer 302 could be removed to expose the back sides 216(1), 216(2) of the deep trenches 218(1), 218(2). Thus, the back side 310 of the bulk body 214 could be removed at the back sides 216(1), 216(2) of the deep trenches 218(1), 218(2). In this example, the removal process used to remove a portion of the bulk body layer 302 may be able to use the back sides 216(1), 216(2) of the deep trenches 218(1), 218(2) as a stop (e.g., a grind stop) for the removal process. The back side 310 of the bulk body 214 could also be removed beyond the back sides 216(1), 216(2) of the deep trenches 218(1), 218(2).

Now that a portion of the bulk body layer 302 is removed towards the back sides 216(1), 216(2) of the deep trenches 218(1), 218(2), the insulation substrate 212 can be disposed on the bulk semiconductor wafer 300 to form the SOI wafer 200D shown in FIG. 3D. In this regard, the insulation substrate 212 is disposed on the back side 310 of the residual bulk body 220 (block 408 in FIG. 4C). The insulation substrate 212 is a material that can provide the electrical isolation desired between the transistor 204 and an adjacent transistor(s) formed in the bulk semiconductor wafer 300. For example, the insulation substrate 212 may be glass to provide greater insulation properties than silicon or other substrates, as an example. Glass is also relatively inexpensive as compared to other materials. Glass may not be able to be used as an insulation substrate in a traditional SOI wafer, because of the high temperatures and pressure used in the FEOL process to form a traditional SOI wafer. Other non-limiting examples of the insulation substrate 212 are molded polymer, glass, sapphire, quartz, and high resistivity silicon. The insulation substrate 212 may be disposed on the back side 310 of the bulk body 214 though a deposition process, as one non-limiting example. In this manner, in this example, the deep trenches 218(1), 218(2) extend to the interface between the back side 310 of the bulk body 214 and a top side 312 of the insulation substrate 212 such that the deep trenches 218(1), 218(2) and the insulation substrate 212 provide electrical isolation between the transistor 204 and adjacent transistors formed in the bulk semiconductor wafer 300. Also, in this example, the insulation substrate 212 is formed in a BEOL process. Thus, the bulk body 214 may not need to be subjected to the higher temperatures and pressures that the bulk semiconductor wafer 300 was exposed to during formation of the transistor 204. Thus, a varactor layer may not be formed in the residual bulk body 220 that would contribute to current leakage from the transistor 204 to adjacent transistors through the insulation substrate 212.

Another optional process may be to add another oxidation or coating layer 314 to the insulation substrate 212 to prevent or reduce impurities from being formed in the insulation substrate 212. For example, the coating layer 314 may be a polymer material.

Lastly, in this example, the carrier wafer 304 can be detached from the SOI wafer 200D in FIG. 3D to provide the SOI wafer 200E in FIG. 3E (block 410 in FIG. 4C). The SOI wafer 200E can be the finalized SOI wafer 200 shown in FIG. 2.

Substrate-transferred, deep trench isolation SOI semiconductor devices formed from bulk semiconductor wafers according to aspects disclosed herein, may be provided in or integrated into in any processor-based device. Examples, without limitation, include a set top box, an entertainment unit, a navigation device, a communications device, a fixed location data unit, a mobile location data unit, a mobile phone, a cellular phone, a smart phone, a tablet, a phablet, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, and an automobile.

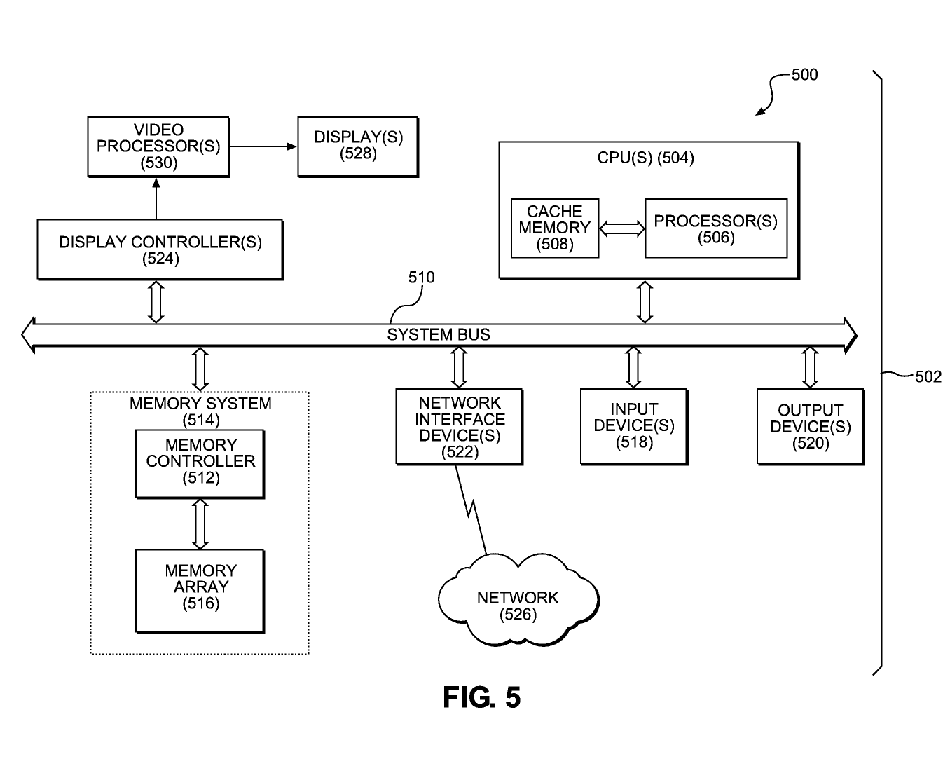

In this regard, FIG. 5 illustrates an example of a processor-based system 500 that can employ circuits 502 that include semiconductor devices comprising substrate-transferred, deep trench isolation SOI wafers formed from bulk semiconductor wafers to improve isolation and reduce current leakage between transistors formed in the SOI wafer. In this example, the processor-based system 500 includes one or more central processing units (CPUs) 504, each including one or more processors 506. The CPU(s) 504 may have cache memory 508 coupled to the processor(s) 506 for rapid access to temporarily stored data. The CPU(s) 504 is coupled to a system bus 510 and can intercouple master and slave devices included in the processor-based system 500. As is well known, the CPU(s) 504 communicates with these other devices by exchanging address, control, and data information over the system bus 510. For example, the CPU(s) 504 can communicate bus transaction requests to a memory controller 512 in a memory system 514 as an example of a slave device. Although not illustrated in FIG. 5, multiple system buses 510 could be provided, wherein each system bus 510 constitutes a different fabric. In this example, the memory controller 512 is configured to provide memory access requests to a memory array 516 in the memory system 514.

Other devices can be connected to the system bus 510. As illustrated in FIG. 5, these devices can include the memory system 514, one or more input devices 518, one or more output devices 520, one or more network interface devices 522, and one or more display controllers 524, as examples. The input device(s) 518 can include any type of input device, including but not limited to input keys, switches, voice processors, etc. The output device(s) 520 can include any type of output device, including but not limited to audio, video, other visual indicators, etc. The network interface device(s) 522 can be any devices configured to allow exchange of data to and from a network 526. The network 526 can be any type of network, including but not limited to a wired or wireless network, a private or public network, a local area network (LAN), a wireless local area network (WLAN), a wide area network (WAN), a BLUETOOTH™ network, and the Internet. The network interface device(s) 522 can be configured to support any type of communications protocol desired.

The CPU(s) 504 may also be configured to access the display controller(s) 524 over the system bus 510 to control information sent to one or more displays 528. The display controller(s) 524 sends information to the display(s) 528 to be displayed via one or more video processors 530, which process the information to be displayed into a format suitable for the display(s) 528. The display(s) 528 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The master and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

1-12. (canceled)

13. A method of fabricating a silicon-on-insulator (SOI) device, comprising:
providing a bulk body layer comprising a top side and a back side;
forming an active semiconductor layer comprising one or more transistors in the top side of the bulk body layer;
forming one or more trenches in the top side of the bulk body layer between adjacent transistors among the one or more transistors, the one or more trenches each comprising a top side disposed toward the top side of the bulk body layer and a back side disposed toward the back side of the bulk body layer;
removing a portion of the bulk body layer from the back side of the bulk body layer towards the back side of the one or more trenches to form a residual bulk body; and
disposing an insulation substrate on a back side of the residual bulk body.

14. The method of claim 13, comprising removing the portion of the bulk body layer from the back side of the bulk body layer to the back side of the one or more trenches.

15. The method of claim 13, comprising removing the portion of the bulk body layer from the back side of the bulk body layer to provide the residual bulk body with one (1) to ten (10) micrometers (μm) of thickness on the back side of the one or more trenches.

16. The method of claim 13, comprising removing the portion of the bulk body layer from the back side of the bulk body layer to expose the back side of the one or more deep trenches from the residual bulk body.

17. The method of claim 13, wherein removing the portion of the bulk body layer comprises grinding the back side of the bulk body layer to the one or more trenches.

18. The method of claim 13, wherein removing the portion of the bulk body layer comprises etching the back side of the bulk body layer to the one or more trenches.

19. The method of claim 13, further comprising forming a connectivity layer above the active semiconductor layer providing connectivity to the one or more transistors in the bulk body layer.

20. The method of claim 19, further comprising disposing a passivation layer above the connectivity layer.

21. The method of claim 20, further comprising attaching a carrier wafer to a top surface of the passivation layer before removing the portion of the bulk body layer from the back side of the bulk body layer.

22. The method of claim 21, further comprising detaching the carrier wafer from the top surface of the passivation layer after disposing the insulation substrate on the back side of the residual bulk body layer.

23. The method of claim 13, wherein the back sides of the one or more trenches are located within one (1) to ten (10) micrometers (μm) from a top side of the insulation substrate.

24. The method claim 19, wherein forming the one or more trenches comprises forming the one or more deep trenches in the top side of the bulk body layer between adjacent transistors among the one or more transistors and between the connectivity layer and a top side of the insulation substrate.

25. The method of claim 13, further comprising forming a channel region in the bulk body layer and separated by a trench among the one or more trenches.

26. The method of claim 25, wherein the one or more transistors each comprise a source and a drain, wherein the channel region is configured to carry a current between the source and the drain.

27. The method of claim 13, further comprising disposing at least one shallow trench shallower than the one or more trenches in the bulk body layer between adjacent transistors among the one or more transistors.

28. The method of claim 13, wherein the insulation substrate is comprised of glass.

29. The method of claim 13, wherein the bulk body layer is comprised of a bulk silicon body.

30. The method of claim 13, further comprising forming a coating layer between the insulation substrate and the bulk body layer.
